(19) United States
(12) Patent Application Publication
(10) Pub. No.: US 2004/0151241 A1
(43) Pub. Date: Aug. 5, 2004

(54) Signal generator using IIR type digital filter and its output stopping method

(76) Inventor: Tsutomu Shimotoyodome, Tokyo (JP)

Correspondence Address: VOLENTINE FRANCOS, PLLC, Suite 150, 12200 Sunrise Vally Drive, Reston, VA, 20191, US

(21) Appl. No.: 10/724,118

(22) Filed: Dec. 1, 2003

(30) Foreign Application Priority Data
Feb. 3, 2003 (JP) JP 2003-025649

(51) Int. Cl. H03K 5/159; H03H 7/30

(52) U.S. Cl. 375/233

(57) ABSTRACT

A signal generator using an IIR type digital filter (recursive type digital filter) having multipliers A and B in a feedback loop. A control unit provided for the signal generator changes coefficients of the multipliers A and B and stops an output signal while maintaining a frequency of the output signal. Even in a stopping step of the output signal, the frequency of the output signal can be maintained at a frequency upon stable output and the generation of harmonics can be minimized.

### BACKGROUND OF THE INVENTION

1. Field of the Invention

The invention relates to a signal generator using an IIR type digital filter and its output stopping method.

2. Related Background Art

According to a conventional signal generator using an IIR type digital filter, at the start of the operation, an impulse δ[n] (δ[n] are set to “all 0” except in the case where n=0) is inputted to the IIR type digital filter expressed by the following difference equation.

y[n]=x[n]+A1*y[n−1]−A2*y[n−2] (1)

By transmitting output data y[n] to a multiplier (coefficient B0) provided out of a feedback loop of the IIR type digital filter, a desired output signal is obtained.

Poles of a transfer function of the equation (1) are set on a unit circle on a Z plane.

It is assumed hereinafter that the output signal denotes a signal obtained by converting the output data (digital signal) into an analog signal.

Usually, the output is forcedly stopped by switching the coefficient B0 of the multiplier to 0, or there is also a case where the coefficient B0 is gradually decreased to 0 and the output is stopped.

A technique for enabling a calculation or the like of the transfer function to be easily executed has also been released (for example, refer to a patent literature 1: JP-A-6-61790 (Abstract)).

In the above prior art, if the operation is forcedly stopped by switching the coefficient B0 of the multiplier to 0, a value of the output data changes suddenly. Such a sudden change in output data is converted into an analog signal and its harmonics penetrate, as noises, peripheral circuits. A problem to be solved such that the noises sometimes cause inconvenience still remains.

In the case of gradually decreasing the coefficient B0 to 0 and the output is stopped as mentioned above, a problem to be solved such that it is necessary to execute arithmetic operations of the coefficient B0 many times and a control method becomes complicated still remains.

### SUMMARY OF THE INVENTION

It is an object of the invention to solve the above problems and realize a signal generator using an IIR type digital filter in which an amount of noises which are generated is small and a control method of stopping the output is simple.

To accomplish the above object, the invention has the following constructions.

<Construction 1>

According to the first aspect of the invention, there is provided a signal generator using an IIR type digital filter having multipliers in a feedback loop, wherein the signal generator includes a control unit which changes coefficients of the multipliers, and the control unit changes the coefficients to predetermined values and stops an output signal while maintaining a frequency of the output signal.

<Construction 2>

According to the second aspect of the invention, there is provided a signal generator using an IIR type digital filter having multipliers in a feedback loop, wherein the signal generator includes a selector to select a predetermined one of a plurality of set values which have been preset as coefficients of the multipliers, the predetermined value is selected, and the output of an output signal is stopped while maintaining a frequency of the output signal.

<Construction 3>

In the signal generator using the IIR type digital filter according to the construction 1 or 2, in the predetermined value, poles of a transfer function of the IIR type digital filter are set to the inside of a unit circle on a Z plane.

<Construction 4>

In the signal generator using the IIR type digital filter according to the construction 3, in the poles of the transfer function, a ratio of a value on an imaginary axis to a value on a real axis of the poles before the coefficients are changed and that after the change of the coefficients are set to an equal value.

<Construction 5>

According to the third aspect of the invention, there is provided an output stopping method of a signal generator using an IIR type digital filter having multipliers in a feedback loop, wherein coefficients of the multiplier are changed while the signal generator is outputting a desired signal, and the output of the desired signal is stopped.

<Construction 6>

In the output stopping method of the signal generator using the IIR type digital filter according to the construction 5, upon change of the coefficient of the multiplier, poles of a transfer function of the IIR type digital filter are moved to the inside of a unit circle on a Z plane.

<Construction 7>

In the output stopping method of the signal generator using the IIR type digital filter according to the construction 6, upon movement of the poles of the transfer function, the poles are moved while a ratio of a value on an imaginary axis to a value on a real axis of the poles before the coefficients are changed and that after the change of the coefficients are maintained at an equal value.

The above and other objects and features of the present invention will become apparent from the following detailed description and the appended claims with reference to the accompanying drawings.

### BRIEF DESCRIPTION OF THE DRAWINGS

FIG. 1 is a block diagram showing a construction of an embodiment 1;

FIG. 2 is a diagram showing poles of a transfer function;

FIG. 3 is a table showing an example of execution numerical values of a difference equation;

FIG. 4 is a diagram showing an example of an execution waveform of the difference equation;

FIG. 5 is a diagram showing a calculation result of the poles;

FIG. 6 is an explanatory diagram of an output signal of the embodiment 1;

FIG. 7 is an explanatory diagram of a movement result of the poles;

FIG. 8 is a block diagram showing a construction of an embodiment 2; and

FIG. 9 is an explanatory diagram of an output signal of the embodiment 2.

### DETAILED DESCRIPTION OF THE PREFERRED EMBODIMENTS

<Embodiment 1>

An embodiment of the invention will be described hereinbelow.

As mentioned above, in the conventional signal generator using the IIR type digital filter, the output is stopped by changing the coefficients of the multipliers provided out of the feedback loop of the IIR type digital filter. In the embodiment, the output is stopped by changing a coefficient of a multiplier provided in the feedback loop. By this method, poles of a transfer function can be moved in accordance with a predetermined principle. Thus, even in an output stopping step, the output signal can be stopped while a frequency of the output signal is maintained at a frequency of the output signal at the time of the stable output, and the generation of harmonics can be minimized. To accomplish the above object, a signal generator using an IIR type digital filter according to the embodiment 1 is constructed as follows.

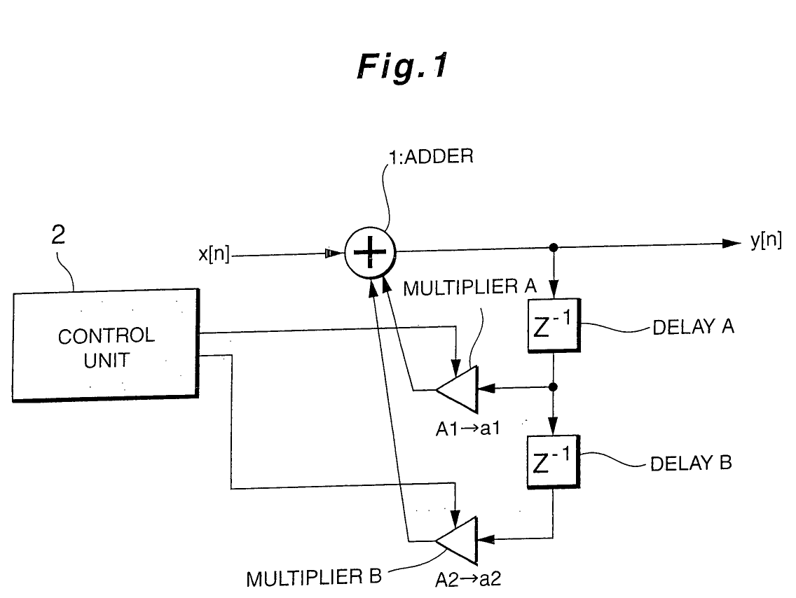

FIG. 1 is a block diagram showing a construction of the embodiment 1.

As shown in the diagram, the signal generator using the IIR type digital filter according to the embodiment 1 comprises an adder 1, a control unit 2, a delay A, a delay B, a multiplier A, and a multiplier B.

The adder 1 is a portion for adding data of a plurality of digital data series and outputting resultant addition data. That is, at a point of time when the operation of the signal generator is started, data of an input data series x[n], data of a feedback data series y[n−1] passing through the delay A and multiplier A, and data of a feedback data series y[n−2] passing through the delay B and multiplier B are added and resultant addition data is outputted. After the start of the operation, the data of the feedback data series y[n−1] passing through the delay A and multiplier A and the data of the feedback data series y[n−2] passing through the delay B and multiplier B are added and resultant addition data is outputted.

The reason why the data series which are added at the start of the operation and the data series which are added after the start of the operation are different is because since the target of the invention is an oscillator, the data of the input data series x[n] has a predetermined value only when the operation is started (n=0) and the data is equal to x[n]=0 at other points of time. It is now assumed that x[0]=B0 and at other time points n<0 and 1≦n, x[n]=0.

The control unit 2 is a portion for changing coefficients of the multipliers A and B while the signal generator using the IIR type digital filter is outputting a desired signal. That is, the control unit 2 is a portion for stopping the output of the signal generator by changing the coefficients of the multipliers A and B to predetermined values during the operation of the signal generator. Usually, in many cases, the control unit 2 is constructed as a part of a function of a CPU or a DSP constructing the signal generator using the IIR type digital filter.

The delay A is a delay element for delaying the data of the output data series by a one-sampling period of time. In this case, the delay A is a delay element for delaying the data of the output data series y[n] by a one-sampling period of time and outputting it as y[n−1]. In the case where the delay element for delaying the data by a one-sampling period of time is Z-transformed and displayed, it is expressed as Z^{-1.}

The delay B is a delay element for further delaying the output data of the delay A by a one-sampling period of time. In this case, the delay B delays the data of the output data series y[n] by a two-sampling period of time and outputs it as y[n−2]. In the case where the delay element for delaying the data by a two-sampling period of time is Z-transformed and displayed, it is expressed as Z^{-2.}

The multiplier A is a portion for multiplying the input data by a predetermined value. In this instance, the multiplier A is a portion for multiplying the output data y[n−1] of the delay A by a constant A1, outputting it as A1*y[n−1], and transferring it to the adder 1. In the invention, the constant A1 is changed by the control unit 2 when the output of the signal generator is stopped.

The multiplier B is a portion for multiplying the input data by a predetermined value. In this instance, the multiplier B is a portion for multiplying the output data y[n−2] of the delay B by a constant −A2, outputting it as −A2*y[n−2], and transferring it to the adder 1. In the invention, the constant A2 is changed by the control unit 2 when the output of the signal generator is stopped.

A relation between the input data and the output data of the signal generator using the IIR type digital filter according to the embodiment 1 is expressed by the following difference equation (1) from the above component portions.

y[n]=x[n]+A1*y[n−1]−A2*y[n−2] (1)

where, y[n]: the output data series of the signal generator using the IIR type digital filter in the embodiment 1

Ordinarily, in many cases, the output data series is converted into an analog sine wave signal after that.

As for x[n], since the target of the invention is the oscillator as mentioned above, x[0]=B0 only at the start of the operation (n=0). It is assumed that at other time points of n<0 and 1≦n, x[n]=0.

It is a well-known fact that in the case where the signal generator using the IIR type digital filter is used as a sine wave oscillator, B0 is set to B0=sin(ωT).

Where, ω: angular frequency of a frequency Fₒ of the output signal

T: one period (1/Fₛ) of a sampling frequency Fₛ

B0 can be given from the outside at the start of the operation of the signal generator using the IIR type digital filter or the last output data stored at the end of the previous operation of the signal generator using the IIR type digital filter can be used.

Similarly, it is also a well-known fact that in the case where the signal generator using the IIR type digital filter is used as a sine wave oscillator, A2 is set to A2=1 and A1 is set to A1=2 cos(ωT).

Where, ω: angular frequency of the output frequency F₀

T: one period (1/Fₛ) of the sampling frequency Fₛ

Subsequently, stability of the signal generator using the IIR type digital filter in the embodiment 1 will be explained.

By Z-transforming the equation (1) and arranging it, the following transfer function H(Z) is obtained.

$$\begin{matrix}Y ( Z ) = \frac{B0 * X ( Z )}{1 - A1 * {Z}^{- 1} + A2 * {Z}^{- 2}} & ( 2 ) \\ ∴ H ( Z ) = \frac{Y ( Z )}{X ( Z )} & \\ = \frac{B0 * {Z}^{2}}{{Z}^{2} - A1 * Z + A2} & \end{matrix}$$

A pole Zₚ is obtained from the above equation (2).

$${Z}_{P} = \frac{A1 \pm \sqrt{{A1}^{2} - 4 * A2}}{2}$$

Since A2 is fixed to 1 as mentioned above, the following equation is obtained.

$${Z}_{P} = \frac{A1 - \sqrt{{A1}^{2} - 4}}{2} \qquad ( 3 )$$

The equation (3) is expressed on a Z plane as follows.

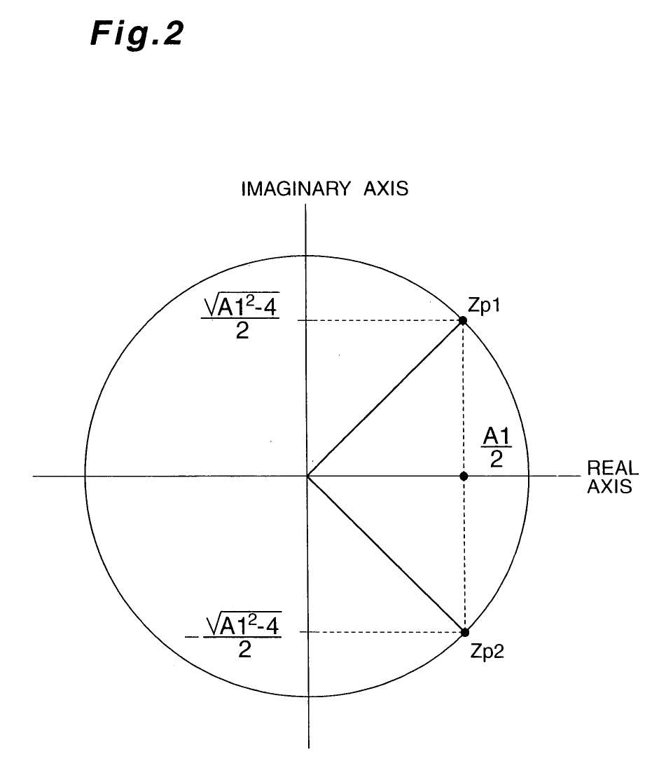

FIG. 2 is a diagram showing the poles of the transfer function.

As shown in the diagram, the equation (3) is expressed as two poles of Zₚ₁ and Zₚ₂ onto the Z plane.

The operation in the case where the signal generator using the IIR type digital filter in the embodiment 1 generates a desired signal on the basis of the above results will be analyzed by specifically setting numerical values.

When the difference equation (1) is solved as follows on the basis of the above results.

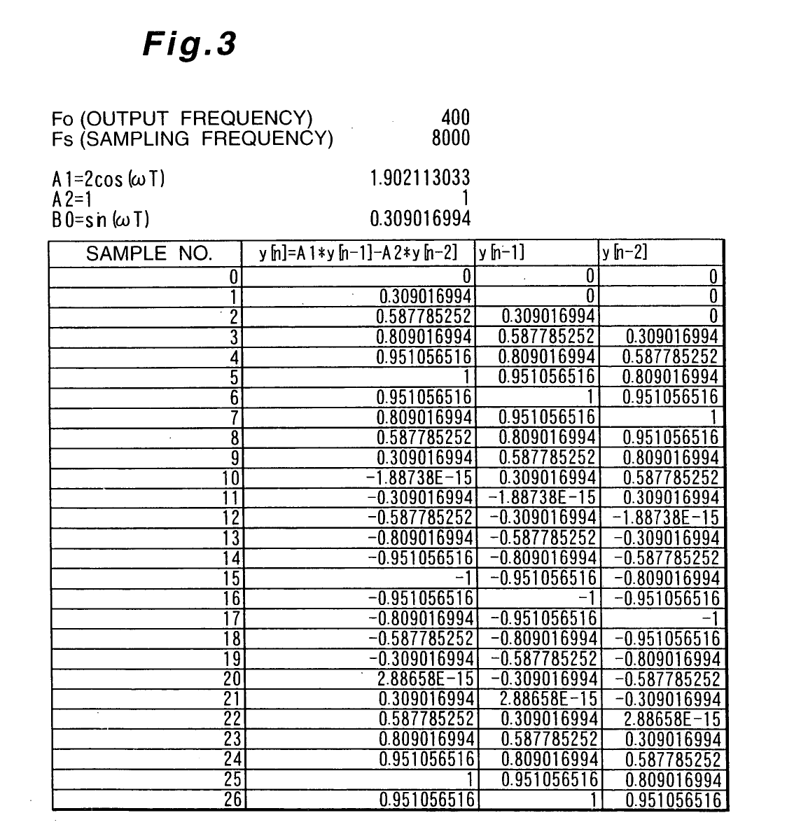

FIG. 3 is a table showing an example of execution numerical values of the difference equation.

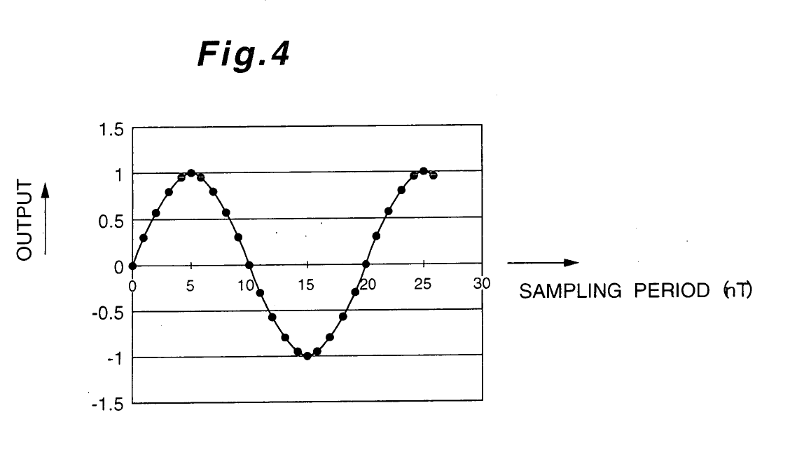

FIG. 4 is a diagram showing an example of an execution waveform of the difference equation.

FIG. 3 shows calculation results of the output data series y[n], the output data series y[n−1] of the multiplier A, and the output data series y[n−2] of the multiplier B in the case where the frequency Fₒ of the output signal is set to 400 Hz, the sampling frequency Fₛ is set to 8000 Hz, A1=2 cos(ωT), A2=1, and B0=sin(ωT) in the difference equation (1) as an example.

FIG. 4 shows a graph of the output data series y[n] in FIG. 3.

In the diagram, an axis of ordinate indicates an output level standardized by an amplitude 1 and an axis of abscissa indicates a time converted into a sampling period.

As shown in FIG. 4, it will be understood that the signal generator using the IIR type digital filter in the embodiment generates the sine wave signal whose amplitude is equal to 1 and whose cycle period is equal to 20 T.

In this case, a value of the pole of the transfer function is as follows from the equation (3).

$$\begin{matrix}{Z}_{P} = \frac{A1 - \sqrt{{A1}^{2} - 4}}{2} \\ = 0.951056516 \pm 0.309016993 ⅈ\end{matrix} \qquad ( 4 )$$

The equation (4) is expressed on the Z plane as follows.

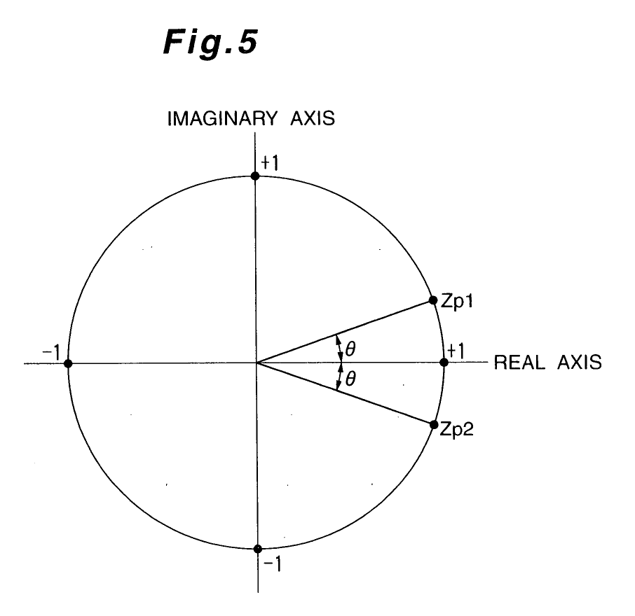

FIG. 5 is a diagram showing a calculation result of the poles.

As shown in FIG. 5, the equation (4) is shown on a unit circle of the Z plane as conjugate complex roots Zₚ₁ and Zₚ₂.

That is, it will be understood that the signal generator using the IIR type digital filter in the embodiment 1 stably generates the desired signal.

Subsequently, a method of stopping the output of the signal generator using the IIR type digital filter in the embodiment 1 will be described.

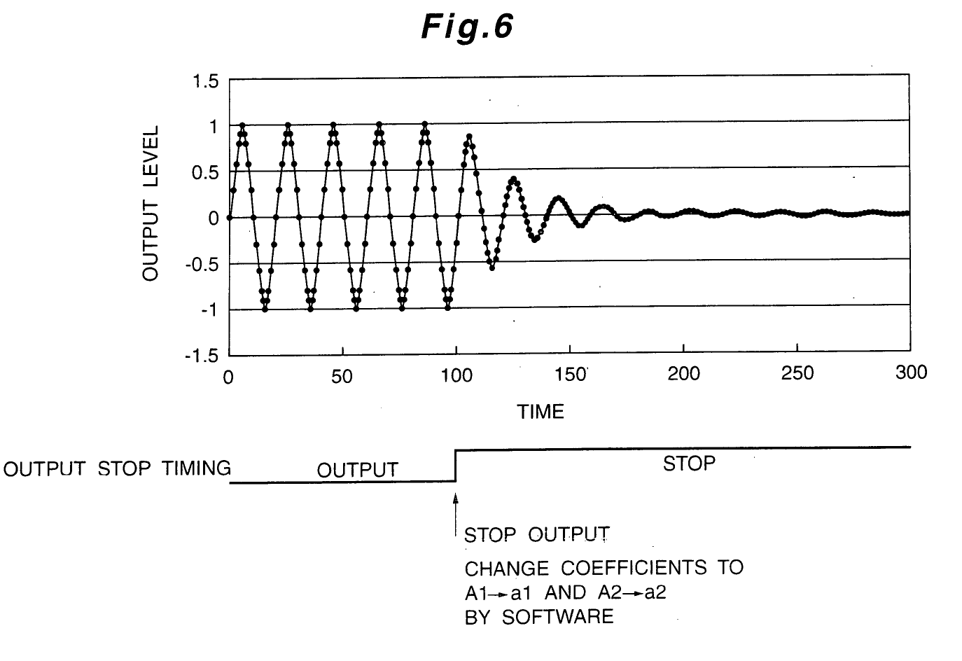

FIG. 6 is an explanatory diagram of the output signal of the embodiment 1.

FIG. 6 shows a state where the signal generator using the IIR type digital filter in the embodiment 1 enters an output stopping state from a stable oscillating state.

In the diagram, an axis of ordinate indicates the output level standardized by the amplitude 1 and an axis of abscissa indicates the time converted into the sampling period.

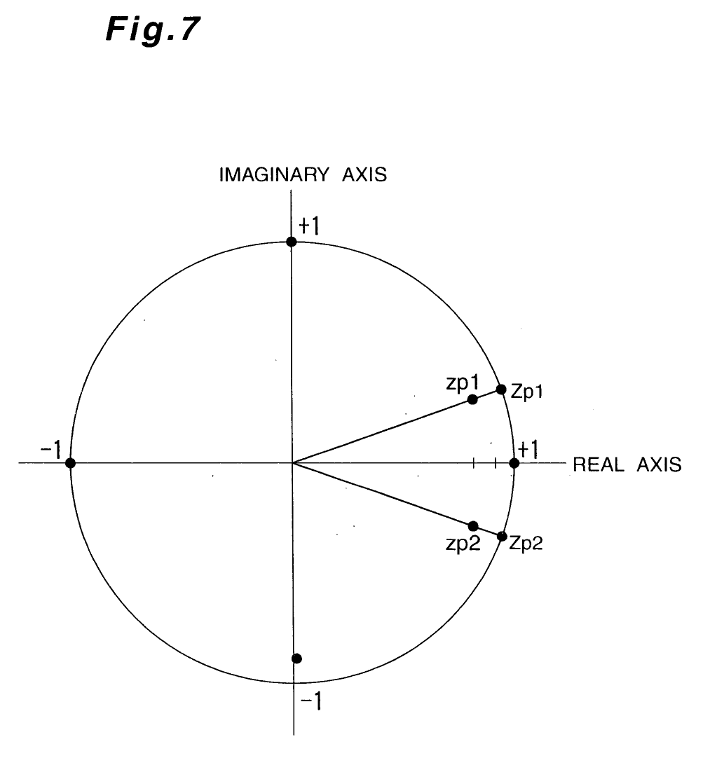

FIG. 7 is an explanatory diagram of a movement result of the poles.

The conjugate complex roots Zₚ₂ and Zₚ₁ on the diagram denote the poles when the signal generator is stably oscillating and zₚ₁ and zₚ₂ indicate poles in a step where the signal generator enters the output stopping state.

The signal generator using the IIR type digital filter in the embodiment 1 starts the oscillation at time 0 and stably generates the output signal whose output frequency Fₒ is equal to 400 Hz and whose sampling frequency Fₛ is equal to 8000 Hz until time 100 T.

At this time, the poles are located in the following positions from the equation (4) (FIG. 7).

Zₚ₁=0.951056516+0.309016993i

Zₚ₂=0.951056516−0.309016993i

The conjugate complex roots Zₚ₁ and Zₚ₂ exist on the unit circle on the Z plane (FIG. 7).

At time 50 T, the control unit 2 (FIG. 1) changes the coefficient of the multiplier A (FIG. 1) from A1 to a1 and changes the coefficient of the multiplier B (FIG. 1) from A2 to a2 and, thereafter, enters the output stopping state.

A method of changing the coefficient of the multiplier A (FIG. 1) and the coefficient of the multiplier B (FIG. 1) in this case will be described in detail hereinbelow.

The change of the coefficients of the multipliers A and B (FIG. 1) is executed by the movement of the pole.

The following two principles are applied to the movement of the poles.

Principle 1

The conjugate complex roots zₚ₁ and Zₚ₂ obtained after the movement are located in the unit circle on the Z plane.

This principle is indispensable to shift the mode of the signal generator using the IIR type digital filter in the embodiment 1 from the stable oscillating state to the output stopping state.

Principle 2

The poles are moved in a manner such that a ratio of a value on an imaginary axis to a value on a real axis of the pole on the Z plane before the coefficients are changed is equal to that after the change of the coefficients.

This principle is necessary to minimize the generation of harmonics while maintaining the same frequency in the step of shifting the mode of the signal generator using the IIR type digital filter in the embodiment 1 from the stable oscillating state to the output stopping state.

An example of the change of coefficients of the multipliers A and B (FIG. 1) based on the above two principles will now be described hereinbelow.

A case of changing the conjugate complex roots Zₚ₁ and Zₚ₂ to the conjugate complex roots zₚ₁ and zₚ₂ in FIG. 7 will be described. Since the conjugate complex roots zₚ₁ and zₚ₂ are located in the unit circle, the principle 1 is satisfied. Since zₚ₁ is located on a straight line connecting an origin and zₚ₁ and zₚ₂ is located on a straight line connecting the origin and Zₚ₂, the principle 2 is also satisfied.

In FIG. 7, a ratio θ of the value on the imaginary axis to the value on the real axis of the pole on the Z plane is obtained as follows from the equation (4).

$$θ = \frac{0.309016993}{0.951056516} = 0.3249695$$

Therefore, assuming that the values on the real axis of the conjugate complex roots zₚ₁ and Zₚ₂ are set to 0.9, the values on the imaginary axis are equal to 0.292427726, that is,

zₚ=0.9±0.292427726i (5)

A1 and A2 are obtained as follows from the equation (5) and a denominator of the equation (2).

A1=1.8 (6)

A2=0.89551395 (7)

At time 100 T, the control unit 2 changes the coefficient of the multiplier A (FIG. 1) to A1=1.8 (the equation 6) and changes the coefficient of the multiplier B (FIG. 1) to A2=0.89551395 (the equation 7).

The poles at this time, that is, the conjugate complex roots zₚ₁ and zₚ₂ in FIG. 7 are located in the unit circle on the Z plane. Also in the output stopping step, since the ratio θ of the value on the imaginary axis to the value on the real axis of the pole on the Z plane is equal to θ in the stable output state, its output frequency is maintained at a frequency at the time of the stable output. Therefore, the generation of the harmonics is minimized.

When the control unit 2 changes the coefficient of the multiplier A (FIG. 1) to A1=1.8 (the equation 6) and changes the coefficient of the multiplier B (FIG. 1) to A2=0.89551, since the poles are moved to the inside of the unit circle on the Z plane as mentioned above, the output of the signal generator is stopped.

In the above description, nothing is mentioned in particular with respect to whether each component portion is constructed by software or constructed by hardware. That is, each component portion can be constructed by software or individually constructed by hardware.

<Embodiment 2>

In the embodiment 2, selectors are provided in place of the control unit in the embodiment 1. The selector selects a predetermined one of a plurality of coefficients which have previously been calculated as coefficients of the multipliers and changes the coefficients of the multipliers in a feedback loop, thereby stopping output of a signal generator using an IIR type digital filter according to the embodiment 2. To accomplish the above object, the signal generator using the IIR type digital filter of the embodiment 2 is constructed as follows.

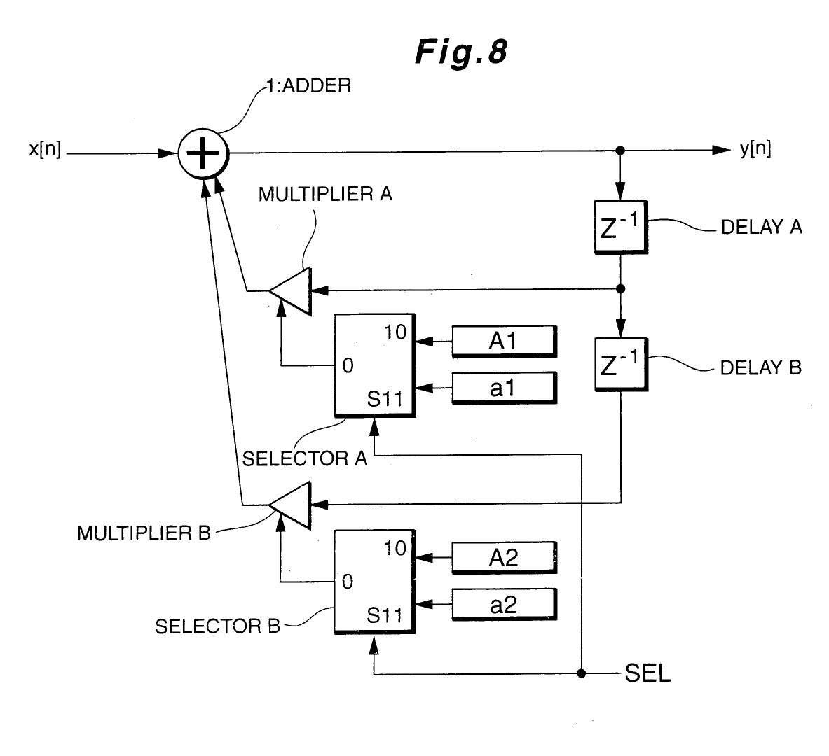

FIG. 8 is a block diagram of a construction of the embodiment 2.

As shown in the diagram, the signal generator using the IIR type digital filter of the embodiment 2 comprises the adder 1, the delay A, the delay B, the multiplier A, the multiplier B, a selector A, and a selector B.

Only points different from the embodiment 1 will be described.

The selector A is a portion for selecting a predetermined one of a plurality of set values which have been preset as a coefficient of the multiplier A and enabling the coefficient of the multiplier A to be changed.

The selector B is a portion for selecting a predetermined one of a plurality of set values which have been preset as a coefficient of the multiplier B and enabling the coefficient of the multiplier B to be changed.

Since all other component portions are similar to those in the embodiment 1, their description is omitted here.

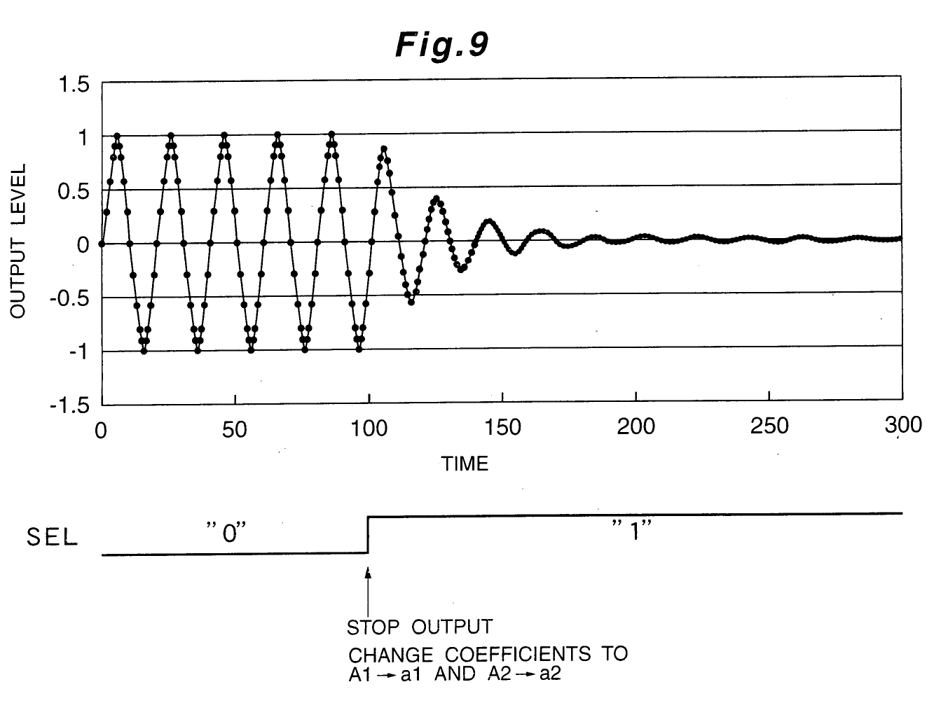

FIG. 9 is an explanatory diagram of an output signal of the embodiment 2.

FIG. 9 shows a state where the signal generator using the IIR type digital filter in the embodiment 2 enters the output stopping state from a normal oscillating state.

In the diagram, an axis of ordinate indicates the output level standardized by the amplitude 1 and an axis of abscissa indicates the time converted into the sampling period.

The selector A is switched by using a selection signal SEL and the coefficient of the multiplier A (FIG. 8) is changed to a preset value A1=1.8 (the equation 6) at time 100 T.

Similarly, the selector B is switched by using the selection signal SEL and the coefficient of the multiplier B (FIG. 8) is changed to a preset value A2=0.89551395 (the equation 7) at time 100 T.

In a manner similar to the embodiment 1, since the poles at this time are the conjugate complex roots zₚ₁ and Zₚ₂ in FIG. 7, the output of the signal generator using the IIR type digital filter in the embodiment 2 attenuates and soon reaches the output stopping state. Even in the step where the output attenuates and soon reaches the output stopping state, since the output frequency is maintained at a frequency upon stable output, the generation of the harmonics is minimized.

By changing the coefficient of the multiplier in the feedback loop and stopping the output as described above, the poles of the transfer function can be moved in accordance with the predetermined principle. Thus, an effect such that even in the output stopping step, the frequency of the output signal can be maintained at the frequency upon stable output, so that the generation of the harmonics can be minimized is obtained.

Since the selector for selecting a predetermined one of the plurality of coefficients which have previously been calculated as coefficients of the multipliers, changing the coefficients of the multipliers in the feedback loop, and stopping the output is provided, an effect such that the generation of the harmonics is minimized and the output can be stopped by the simple hardware construction is obtained.

The present invention is not limited to the foregoing embodiments but many modifications and variations are possible within the spirit and scope of the appended claims of the invention.

What is claimed is:

1. A signal generator using an IIR type digital filter having multipliers in a feedback loop, wherein
said signal generator includes a control unit which changes coefficients of said multipliers, and
said control unit changes said coefficients to predetermined values and stops an output signal while maintaining a frequency of said output signal.

2. A signal generator using an IIR type digital filter having multipliers in a feedback loop, wherein
said signal generator includes a selector to select a predetermined one of a plurality of set values which have been preset as coefficients of said multipliers, and
said predetermined value is selected and output of an output signal is stopped while maintaining a frequency of said output signal.

3. The generator according to claim 1 or 2, wherein
in said predetermined value, poles of a transfer function of said IIR type digital filter are set to an inside of a unit circle on a Z plane.

4. The generator according to claim 3, wherein
in the poles of said transfer function,
a ratio of a value on an imaginary axis to a value on a real axis of said poles before said coefficients are changed and that after the change of said coefficients are set to an equal value.

5. An output stopping method of a signal generator using an IIR type digital filter having multipliers in a feedback loop, comprising the steps of:
changing coefficients of said multipliers while said signal generator is outputting a desired signal and stopping the output of said desired signal.

6. The method according to claim 5, wherein
upon change of the coefficient of said multiplier, poles of a transfer function of said IIR type digital filter are moved to an inside of a unit circle on a Z plane.

7. The method according to claim 6, wherein
upon movement of the poles of said transfer function, the poles are moved while a ratio of a value on an imaginary axis to a value on a real axis of said poles before said coefficients are changed and that after the change of said coefficients are maintained at an equal value.
